(19) United States
(12) Patent Application Publication
(10) Pub. No.: US 2025/0374838 A1
(43) Pub. Date: Dec. 4, 2025

(54) SEMICONDUCTOR DEVICE AND METHOD FOR OPERATING THE SAME

(71) Applicant: KOREA ADVANCED INSTITUTE OF SCIENCE AND TECHNOLOGY, Daejeon (KR)

(72) Inventors: Heejun YANG, Daejeon (KR); Eunji HWANG, Daejeon (KR)

(73) Assignee: KOREA ADVANCED INSTITUTE OF SCIENCE AND TECHNOLOGY, Daejeon (KR)

(21) Appl. No.: 19/053,943

(22) Filed: Feb. 14, 2025

(30) Foreign Application Priority Data
May 29, 2024 (KR) 10-2024-0070337
Oct. 23, 2024 (KR) 10-2024-0145735

(51) Int. Cl. H10N 70/00; G11C 13/00; H10B 63/00; H10D 30/01; H10D 30/69; H10D 64/01; H10D 64/68

(52) U.S. Cl. CPC H10N 70/8828; G11C 13/004; H10B 63/30; H10D 30/0415; H10D 30/701; H10D 64/033; H10D 64/689; H10N 70/841; H10N 70/8822; H10N 70/8825

(57) ABSTRACT

A method for operating a semiconductor device, the method according to the present invention includes applying a first bias voltage to a gate pattern, and storing first data in response to the first bias voltage, wherein contact resistance between an electrode pattern and a ferroelectric pattern is changed from a first resistance state to a second resistance state in response to the first bias voltage, the first data is stored based on the change from the first resistance state to the second resistance state, and the ferroelectric pattern is interposed between the gate pattern and the electrode pattern.

### CROSS-REFERENCE TO RELATED APPLICATIONS

This U.S. non-provisional patent application claims priority under 35 U.S.C. § 119 of Korean Patent Application Nos. 10-2024-0070337, filed on May 29, 2024, and 10-2024-0145735, filed on Oct. 23, 2024, the entire contents of which are hereby incorporated by reference.

### BACKGROUND

This study was conducted with the support of the Samsung Future Technology Promotion Project (Project number: SRFC-MA1701-52/Project title: Ferroelectric-phase transition material-based Van der Waals heterostructure neuristor integrated circuit).

The present invention relates to a semiconductor device, and a method for operating the same, and more particularly, to a semiconductor device which provides a new type of memory device, and a method for operating the semiconductor device. In addition, the present invention relates to a semiconductor device with improved integration and a method for operating the same.

Semiconductor devices have been in the spotlight as an important element in the electronics industry due to the characteristics such as miniaturization, multi-functionality, and/or low manufacturing cost. Semiconductor devices may be classified into a semiconductor memory device for storing logic data, a semiconductor logic device for calculating and processing logic data, and a hybrid semiconductor device including a memory element and a logic element.

Particularly, ferroelectric-based non-volatile memory devices have attracted attention more than silicon-based volatile memory devices. A ferroelectric is a material which has polarization without an external electric field, and may be used as a non-volatile memory device by using such a characteristic.

In general, ferroelectric-based non-volatile memory devices utilize an insulating material with ferroelectric characteristics. Recently, ferroelectric characteristics have been discovered in metals and semiconductor materials, on which various studies are being conducted.

### SUMMARY

A technical object to be achieved by the present invention is to provide a semiconductor device which provides a new type of memory device, and a method for operating the semiconductor device.

Another technical object to be achieved by the present invention is to provide a semiconductor device with improved integration and a method for operating the same.

Objects to be achieved by the present invention are not limited to the objects mentioned above, and other objects that are not mentioned above will be clearly understood by those skilled in the art from the following description.

A method for operating a semiconductor device, the method according to the present invention includes applying a first bias voltage to a gate pattern, and storing first data in response to the first bias voltage, wherein contact resistance between an electrode pattern and a ferroelectric pattern may be changed from a first resistance state to a second resistance state in response to the first bias voltage, the first data may be stored based on the change from the first resistance state to the second resistance state, and the ferroelectric pattern may be interposed between the gate pattern and the electrode pattern.

A semiconductor device according to the present invention includes a substrate, a ferroelectric pattern on the substrate, an electrode pattern in contact with the ferroelectric pattern between the ferroelectric pattern and the substrate, and a gate pattern adjacent to the ferroelectric pattern, and configured to control the direction of polarization of the ferroelectric pattern, wherein the ferroelectric pattern may be interposed between the gate pattern and the electrode pattern, contact resistance between the ferroelectric pattern and the electrode pattern may be changed from a first resistance state to a second resistance state in response to a first bias voltage applied to the gate pattern, and the first data may be stored based on the change from the first resistance state to the second resistance state.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view showing a semiconductor device according some embodiments of the present invention;

FIG. 2A and FIG. 2B are enlarged views corresponding to E1 of FIG. 1;

FIG. 2C is a view including includes a cross-sectional view and a circuit diagram of some components of FIG. 1;

FIGS. 3A and 3B are graphs illustrating conductance of a ferroelectric pattern according to a voltage applied to a gate pattern;

FIG. 4A and FIG. 4B are enlarged views corresponding to the E1 of FIG. 1;

FIG. 5 is a diagram illustrating a change in an atomic structure of a ferroelectric pattern according to a polarization state of the ferroelectric pattern;

FIG. 6 is a graph illustrating a change in transferred electron density according to an electric field applied to a ferroelectric pattern according to a polarization state of the ferroelectric pattern;

FIG. 7 is a graph illustrating a difference in transferred charges and band bending according to a polarization state of a ferroelectric pattern;

FIG. 8A and FIG. 8B are cross-sectional views showing a semiconductor device according to some embodiments of the present invention;

FIG. 9 is a graph illustrating conductance of a ferroelectric pattern according to each of a voltage applied to an upper gate pattern of FIG. 8A, and a voltage applied to a lower gate pattern of FIG. 8B;

FIG. 10 is a cross-sectional view showing a semiconductor device according some embodiments of the present invention;

FIG. 11 is a cross-sectional view showing a semiconductor device according some embodiments of the present invention;

FIG. 12 is a cross-sectional view showing a semiconductor device according some embodiments of the present invention;

FIG. 13 is a cross-sectional view showing a semiconductor device according some embodiments of the present invention;

FIG. 14 is a cross-sectional view showing a semiconductor device according some embodiments of the present invention; and

FIG. 15 is a cross-sectional view showing a semiconductor device according some embodiments of the present invention.

### DETAILED DESCRIPTION

Hereinafter, in order to describe the present invention in more detail, embodiments according to the present invention will be described in more detail with reference to the accompanying drawings.

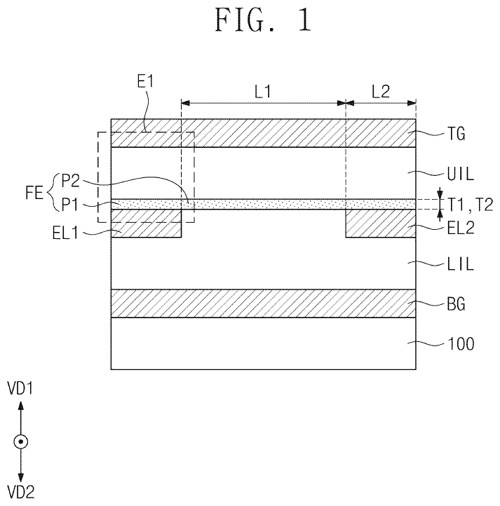

FIG. 1 is a cross-sectional view showing a semiconductor device according some embodiments of the present invention.

Referring to FIG. 1, the semiconductor device may include a substrate 100, a lower gate pattern BG on the substrate 100, a lower insulating layer LIL on the lower gate pattern BG, a first electrode pattern EL1 and a second electrode pattern EL2 on the lower insulating layer LIL, a ferroelectric pattern FE on the first electrode pattern EL1 and the second electrode pattern EL2, an upper insulating layer UIL on the ferroelectric pattern FE, and an upper gate pattern TG on the upper insulating layer UIL.

As an example, the substrate 100 may be a semiconductor substrate, an insulator substrate, a silicon-on-insulator SOI substrate, or a germanium-on-insulator GOI substrate. As an example, the semiconductor substrate may be a silicon substrate, a germanium substrate, or a silicon-germanium substrate. As an example, the semiconductor substrate may include an insulating material (e.g., SiO₂).

The lower gate pattern BG may be provided on an upper surface of the substrate 100. As an example, the lower gate pattern BG may include a conductor. As an example, the lower gate pattern BG may include graphene.

The lower insulating layer LIL may be provided on an upper surface of the lower gate pattern BG. Although not illustrated in the drawing, the lower insulating layer LIL may cover the upper surface and side surfaces of the lower gate pattern BG. As an example, the lower insulating layer LIL may include hexagonal boron nitride (h-BN).

The first electrode pattern EL1 and the second electrode pattern EL2 may be provided in the lower insulating layer LIL. The first electrode pattern EL1 and the second electrode pattern EL2 may be arranged to be spaced apart from each other in one direction. Each of the first electrode pattern EL1 and the second electrode pattern EL2 may include a conductor. As an example, each of the first electrode pattern EL1 and the second electrode pattern EL2 may include a metal material which is resistant against oxidation. As an example, each of the first electrode pattern EL1 and the second electrode pattern EL2 may include Pt.

The ferroelectric pattern FE may be provided on an upper surface of each of the first electrode pattern EL1 and the second electrode pattern EL2. The ferroelectric pattern FE may be provided on an upper surface of the lower insulating layer LIL. The ferroelectric pattern FE may extend in a direction in which the first electrode pattern EL1 and the second electrode pattern EL2 are spaced apart from each other on the lower insulating layer LIL. The ferroelectric pattern FE may include a ferroelectric material having a polarization characteristic by an electric field applied to the ferroelectric pattern FE. The ferroelectric pattern FE may have a spontaneous dipole (electric dipole), i.e., spontaneous polarization. The ferroelectric pattern FE has remnant polarization due to a dipole even in a state in which there is no external electric field. In addition, the direction of polarization may be switched by an external electric field.

The ferroelectric pattern FE may include at least one of a semiconductor and a conductor. As an example, the ferroelectric pattern FE may include a conductive ferroelectric material. As an example, if the ferroelectric pattern FE includes a semiconductor, the semiconductor may include at least one of In₂Se₃, SnS, SnTe, MoS₂, and WS₂. As an example, if the ferroelectric pattern FE includes a conductor, the conductor may include at least one of WTe₂, MoTe₂, and Mo_{0.5}W_{0.5}Te₂.

Each of the first electrode pattern EL1 and the second electrode pattern EL2 may be in contact with the ferroelectric pattern FE. As an example, a lower surface of the ferroelectric pattern FE may be in contact with an upper surface of the first electrode pattern EL1 and an upper surface of the second electrode pattern EL2. Accordingly, contact resistance may be formed between the upper surface of the first electrode pattern EL1 and the lower surface of the ferroelectric pattern FE and between the upper surface of the second electrode pattern EL2 and the lower surface of the ferroelectric pattern FE. As an example, if the ferroelectric pattern FE includes the above-described conductor, each of the first electrode pattern EL1 and the second electrode pattern EL2 may form an ohmic contact with the ferroelectric pattern FE.

The ferroelectric pattern FE may include first regions P1 vertically overlapping the first electrode pattern EL1 and the second electrode pattern EL2, and a second region P2 between the first regions P1. The second region P2 of the ferroelectric pattern FE may not vertically overlap each of the first electrode pattern EL1 and the second electrode pattern EL2. Since the ferroelectric pattern FE is interposed between each of the first electrode pattern EL1 and the second electrode pattern EL2 and the upper gate pattern TG to be described later, all of the first regions P1 and the second region P2 of the ferroelectric pattern FE may be affected by an electric field generated by a voltage applied to the upper gate pattern TG to be described later.

With respect to the direction in which the ferroelectric pattern FE extends, the second region P2 of the ferroelectric pattern FE may have a first length L1, and each of the first regions P1 may have a second length L2. With respect to a vertical direction VD1, the second region P2 of the ferroelectric pattern FE may have a first thickness T1, and each of the first regions PI may have a second thickness T2. The vertical direction VD1 may be a direction perpendicular to the upper surface of the substrate 100.

The first length L1 may be 10 nm to 500 nm. The second length L2 may be 600 nm to 1 um. The first thickness T1 may be substantially the same as the second thickness T2, but is not limited thereto. The first regions P1 and the second region P2 of the ferroelectric pattern FE may be a monolayer or more. As an example, the second region P2 of the ferroelectric pattern FE may be a monolayer.

The upper insulating layer UIL may be provided on an upper surface of the ferroelectric pattern FE. Although not illustrated in the drawing, the upper insulating layer UIL may cover the upper surface and side surfaces of the ferroelectric pattern FE. As an example, the upper insulating layer UIL may include hexagonal boron nitride (h-BN).

The upper gate pattern TG may be provided on an upper surface of the upper insulating layer UIL. As an example, the upper gate pattern TG may include a conductor. As an example, the upper gate pattern TG may include graphene.

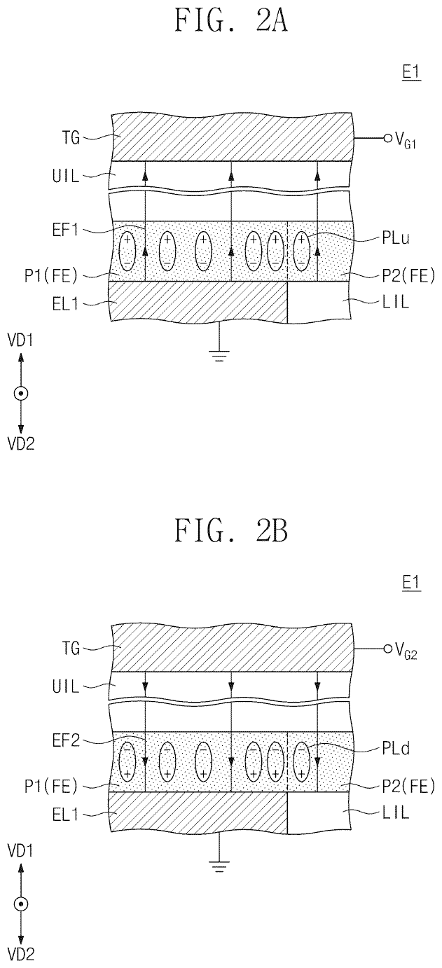

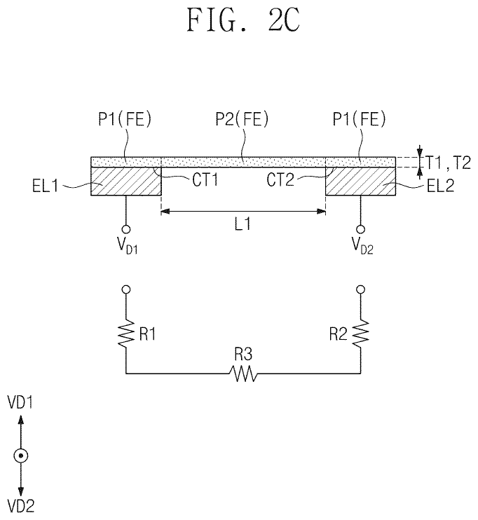

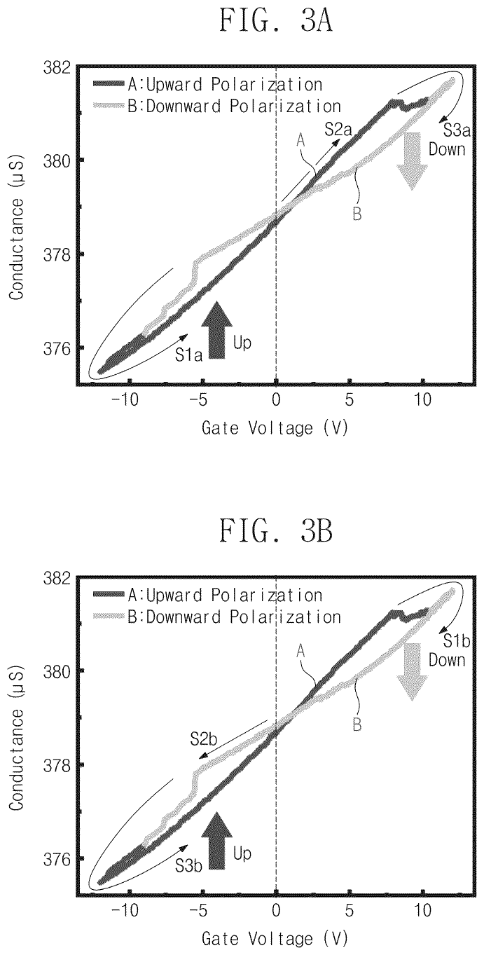

FIG. 2A and FIG. 2B are enlarged views corresponding to E1 of FIG. 1. FIG. 2C is a view including includes a cross-sectional view and a circuit diagram of some components of FIG. 1. FIG. 3A and FIG. 3B are graphs illustrating conductance of a ferroelectric pattern according to a voltage applied to a upper gate pattern.

Referring to FIG. 2A, FIG. 2B, FIG. 2C, FIG. 3A, and FIG. 3B, a semiconductor device having a cross-sectional view described with reference to FIG. 1 is provided as an experimental example. In this experimental example, the ferroelectric pattern FE is composed of WTe₂, and each of the first electrode pattern

EL1 and the second electrode pattern EL2 is composed of Pt. In addition, each of the upper gate pattern TG and the lower gate pattern BG is composed of graphene, and each of the upper insulating layer UIL and the lower insulating layer LIL is composed of h-BN. The ferroelectric pattern FE is composed of a bilayer. The first thickness T1 and the second thickness T2 are formed to be substantially the same.

FIG. 2A is a cross-sectional view showing that a first electric field EF1 is applied to the ferroelectric pattern FE in the vertical direction VD1. In order for the first electric field EF1 to be applied in the above direction VD1, a gate voltage may be applied to the upper gate pattern TG. In this case, the value of the corresponding voltage may be less than 0[V]. Since the first electric field EF1 is applied, polarization of the ferroelectric pattern FE may be changed to an up-polarization direction PLu. In this case, the voltage applied to the upper gate pattern TG may be a first threshold voltage V_{G1}. In this experimental example, the first threshold voltage V_{G1} is −10[V] (see FIG. 3A and FIG. 3B).

Next, FIG. 2B is a cross-sectional view showing that a second electric field EF2 is applied to the ferroelectric pattern FE in an opposite direction VD2 to the vertical direction VD1. In order for the second electric field EF2 to be applied in the above direction VD2, a gate voltage may be applied to the upper gate pattern TG. In this case, the value of the corresponding voltage may be greater than 0[V]. Since the second electric field EF2 is applied, the polarization of the ferroelectric pattern FE may be changed to a down-polarization direction PLd. In this case, the voltage applied to the upper gate pattern TG may be a second threshold voltage V_{G2}. In this experimental example, the second threshold voltage V_{G2} is 10[V] (see FIG. 3A and FIG. 3B).

FIG. 2C is a cross-sectional view and a circuit diagram showing the measurement of resistance of the ferroelectric pattern FE. Specifically, the ferroelectric pattern FE may have a first contact resistance R1 in a portion CT1 in which the first region P1 and the first electrode pattern EL1 are in contact. The ferroelectric pattern FE may have a second contact resistance R2 in a portion CT2 in which the first region P1 and the second electrode pattern EL2 are in contact. The ferroelectric pattern FE may have an internal resistance R3 inside the second region P2. In order to measure the above-described resistances, as an example, a two-terminal measurement method may be performed. In this case, a first read voltage V_{D1} may be applied to the first electrode pattern EL1, and the second read voltage V_{D2} may be applied to the second electrode pattern EL2. As an example, the first read voltage V_{D1} may be a ground voltage. As an example, the value of the second read voltage VD2 may greater than 0[V]. By applying the above-described voltages to the first electrode pattern EL1 and the second electrode pattern EL2, the first contact resistance R1, the second contact resistance R2, and the internal resistance R3 may be measured utilizing the Ohm's law.

Each of the first contact resistance R1 and the second contact resistance R2 measured through the above-described measurement method (e.g., the two-terminal measurement method) may be greater than the internal resistance R3. As an example, each of the first contact resistance R1 and the second contact resistance R2 may be several tens of times greater than the internal resistor R3. Accordingly, a change in the total resistance (i.e., R1+R2+R3) of the ferroelectric pattern FE may be dominant in changes in the first contact resistance R1 and the second contact resistance R2. The change in the total resistance (i.e., R1+R2+R3) of the ferroelectric pattern FE may not be dominant in a change in the internal resistance R3.

The x-axis of each graph of FIG. 3A and FIG. 3B is a gate voltage, and corresponds to a gate voltage applied to the upper gate pattern TG. In this case, a voltage applied to the lower gate pattern BG (see BG of FIG. 1) may be a ground voltage. The y-axis of the graphs of FIG. 3A and FIG. 3B corresponds to a value of conductance of the ferroelectric pattern FE. Specifically, the sum of the first contact resistance R1, the second contact resistance R2, and the internal resistance R3 is converted into a value of conductance. By converting a value of resistance into a value of conductance, a change in the value of each of the first contact resistance R1 and the second contact resistance R2 may be better reflected. Line A represents a value of conductance when the ferroelectric pattern FE is in the up-polarization direction PLu. Line B represents a value of conductance when the ferroelectric pattern FE is in the down-polarization direction PLd.

With reference to FIG. 2A, FIG. 2B, FIG. 2C, FIG. 3A, and FIG. 3B, writing and reading operation methods of a semiconductor device according to some embodiments of the present invention will be described in detail.

First, referring to FIG. 3A, a conductance value of the ferroelectric pattern FE according to a voltage applied to the upper gate pattern TG has a hysteresis loop. As an example, as the voltage applied to the upper gate pattern TG changes from zero to the first threshold voltage V_{G1}, the conductance value decreases (S1a). Thereafter, as the first threshold voltage V_{G1} is applied, a polarization direction of the ferroelectric pattern FE is changed to the up-polarization direction PLu, resulting in rapidly decreasing the conductance value (S1a). Again, as the voltage applied to the upper gate pattern TG changes from the first threshold voltage V_{G1} to the second threshold voltage V_{G2}, the conductance value increases (S2a). Thereafter, as the second threshold voltage V_{G2} is applied, the polarization direction of the ferroelectric pattern FE is changed to the down-polarization direction PLd, resulting in rapidly decreasing the conductance value (S3a).

Next, referring to FIG. 3B, the conductance value of the ferroelectric pattern FE according to the voltage applied to the upper gate pattern TG has a hysteresis loop. As an example, as the voltage applied to the upper gate pattern TG changes from zero to the second threshold voltage V_{G2}, the conductance value increases (S1b). Thereafter, as the second threshold voltage V_{G2} is applied, the polarization direction of the ferroelectric pattern FE is changed to the down-polarization direction PLd, resulting in rapidly decreasing the conductance value (S1b). Again, as the voltage applied to the upper gate pattern TG changes from the second threshold voltage V_{G2} to the first threshold voltage V_{G1}, the conductance value decreases (S2b). Thereafter, as the first threshold voltage V_{G1} is applied, a polarization direction of the ferroelectric pattern FE is changed to the up-polarization direction PLu, resulting in rapidly decreasing the conductance value (S3b).

To summarize FIG. 3A and FIG. 3B, in each of a first section in which the voltage applied to the upper gate pattern TG is 0[V] or greater and a second section in which the voltage applied to the upper gate pattern TG is 0[V] or less, a value of conductance in the up-polarization direction PLu and a value of conductance in the down-polarization direction PLd may be different from each other. In other words, in each of the first section and the second section, a value of contact resistance in the up-polarization direction PLu and a value of contact resistance in the down-polarization direction PLd may be different from each other. By using the above-described characteristic, the semiconductor device may be utilized as a memory device. Specifically, during a reading operation, depending on whether the voltage applied to the upper gate pattern TG is the first section or second section, data writing and reading methods may vary.

During the reading operation of the semiconductor device according to some embodiments of the present invention, if the voltage applied to the upper gate pattern TG is in the first section, the data writing and reading methods of the semiconductor device may be performed as follows.

The value of conductance in the up-polarization direction PLu may be greater than the value of conductance in the down-polarization direction PLd. In other words, the contact resistance in the up-polarization direction PLu may be less than the contact resistance in the down-polarization direction PLd. In summary, the contact resistance in the up-polarization direction PLu may be in a low resistance state (LRS), and the contact resistance in the down polarization direction PLd may be in a high resistance state (HRS). Therefore, when the contact resistance of the ferroelectric pattern FE is LRS, data “1” may be stored. On the other hand, if the applied voltage is 0[V] or greater, and when the contact resistance of the ferroelectric pattern FE is HRS, data “0” may be stored.

In other words, changing the polarization direction of the ferroelectric pattern FE to the up-polarization direction PLu in response to the first threshold voltage V_{G1} may be an operation of writing the data “1,” and changing the polarization direction of the ferroelectric pattern FE to the down-polarization direction PLd in response to the second threshold voltage V_{G2} may be an operation of writing the data “0.” In addition, after the data writing operation, the reading operation may be performed to read the stored data by applying the voltage of the first section to the upper gate pattern TG, and by applying a first read voltage V_{D1} to the first electrode pattern EL1, and a second read voltage V_{D2} to the second electrode pattern EL2.

During a reading operation of a semiconductor device according to other embodiments of the present invention, if the voltage applied to the upper gate pattern TG is in the second section, data writing and reading methods of the semiconductor device may be performed as follows.

The value of conductance in the down-polarization direction PLd may be greater than the value of conductance in the up-polarization direction PLu. In other words, the contact resistance in the down-polarization direction PLd may be less than the contact resistance in the up-polarization direction PLu. In summary, if the voltage applied to the upper gate pattern TG is in the second section, the contact resistance in the down-polarization direction PLd may be the LRS, and the contact resistance in the up-polarization direction PLu may be the HRS.

In other words, changing the polarization direction of the ferroelectric pattern FE to the down-polarization direction PLd in response to the second threshold voltage V_{G2} may be the operation of writing the data “1,” and changing the polarization direction of the ferroelectric pattern FE to up-polarization direction PLu in response to the first threshold voltage V_{G1} may be the operation of writing the data “0.” In addition, after the data writing operation, the reading operation may be performed to read the stored data by applying the voltage of the second section to the upper gate pattern TG, and by applying the first read voltage V_{D1} to the first electrode pattern EL1, and the second read voltage V_{D2} to the second electrode pattern EL2.

During the reading operation of the semiconductor device, the writing operation method may vary depending on whether a voltage applied to the upper gate pattern TG is in the first section or is in the second section, which may be variously selected/changed by a person skilled in the art.

According to the concept of the present invention, contact resistance between the ferroelectric pattern FE and the first electrode pattern EL1 and between the ferroelectric pattern FE and the second electrode pattern EL2 may be switched according to the polarization direction of the ferroelectric pattern FE. By utilizing the characteristic in which contact resistance is switched, a semiconductor device may be utilized as a contact resistance switching-based memory device. Therefore, the semiconductor device of the present invention may provide a new type of memory device.

Furthermore, the semiconductor device of the present invention, which is utilized as a contact resistance switching-based memory device, may not be affected by a short channel effect compared to a memory device utilizing switching of internal resistance of the ferroelectric pattern FE. Specifically, as the length L1 of the second region P2 of the ferroelectric pattern FE decreases, the switching characteristic of the internal resistance of the ferroelectric pattern FE may be affected by a voltage applied to each of the first electrode pattern EL1 and the second electrode pattern EL2. On the other hand, even if the length L1 of the second region P2 of the ferroelectric pattern FE decreases, the switching characteristic of the contact resistance between the ferroelectric pattern FE and each of the first electrode pattern ELI and the second electrode pattern EL2 may not be affected. Accordingly, the semiconductor device of the present invention, which is utilized as a contact resistance switching-based memory device, may be formed to have a small length L1 of the second region P2 of the ferroelectric pattern FE. Thus, the integration of the semiconductor device may be improved.

In addition, if the ferroelectric pattern FE becomes a monolayer, a switching characteristic of the internal resistance of the ferroelectric pattern FE may not be found. Accordingly, a semiconductor device which utilizes the switching of the internal resistance of the ferroelectric pattern FE may not be utilized as a memory device. On the other hand, since the contact resistance of the semiconductor device of the present invention is formed at contact surfaces (CT1 and CT2 of FIG. 2C) between the ferroelectric pattern FE and each of the first electrode pattern EL1 and the second electrode pattern EL2, the switching characteristic of the contact resistance may not be affected by the thickness T1 and T2 of the ferroelectric pattern FE. Accordingly, the semiconductor device of the present invention, which is utilized as a contact resistance switching-based memory device, may be formed to have small thicknesses T1 and T2 of the ferroelectric pattern FE. Thus, the integration of the semiconductor device may be improved.

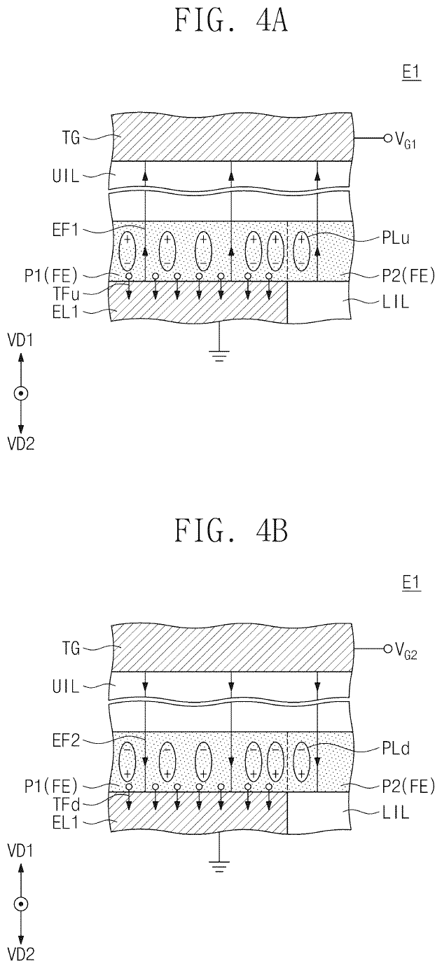

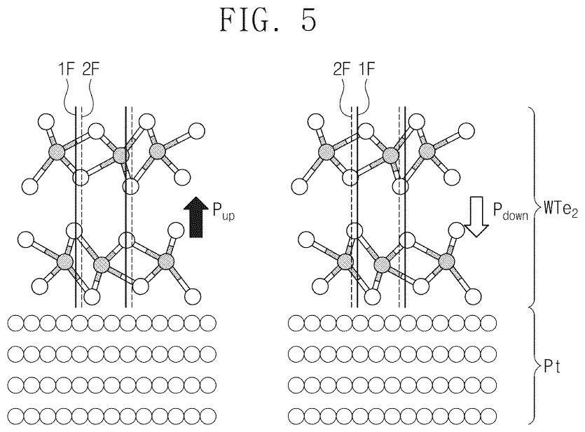

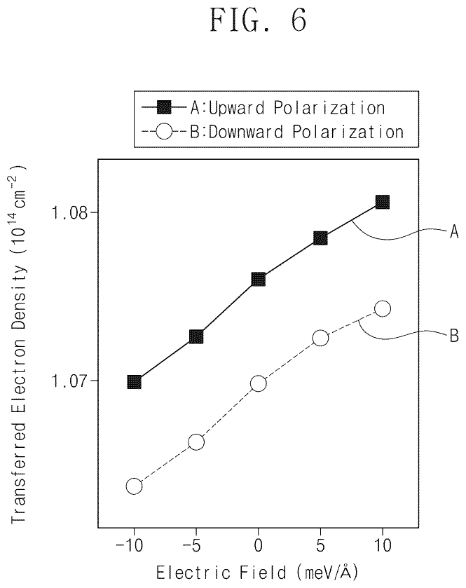

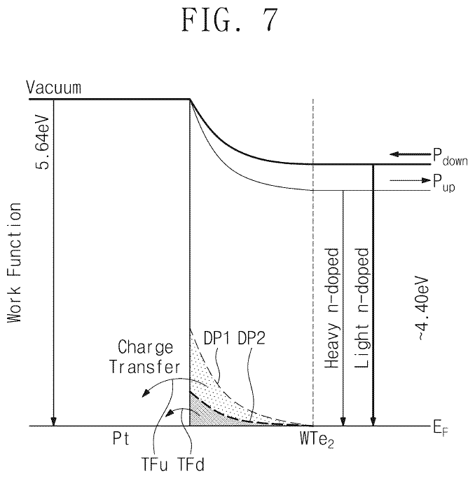

FIG. 4A and FIG. 4B are enlarged views corresponding to the E1 of FIG. 1. FIG. 5 is a diagram illustrating a change in an atomic structure of the ferroelectric pattern FE according to a polarization state of the ferroelectric pattern FE. FIG. 6 is a graph illustrating a change in transferred electron density according to an electric field applied to the ferroelectric pattern FE according to a polarization state of the ferroelectric pattern FE. FIG. 7 is a graph illustrating a difference in charge transfer according to a polarization state of the ferroelectric pattern FE through an band bending.

With reference to FIG. 4A, FIG. 4B, FIG. 5, FIG. 6, and FIG. 7, the reason why the contact resistance is changed according to the polarization state of the ferroelectric pattern FE of the experimental example described above will be described in detail.

The atomic structure and the arrangement of the bilayer of the ferroelectric pattern FE may be changed depending on the polarization state. Specifically, in the bilayer of the ferroelectric pattern FE, a Te atom in a first layer 1F and a Te atom in a second layer 2F may be subject to sliding depending on the polarization state of the ferroelectric pattern FE (see FIG. 5). Here, in the bilayer, the first layer 1F is interposed between the second layer 2F and Pt (in other words, the first electrode pattern EL1 or the second electrode pattern EL2).

Specifically, depending on the polarization state of the ferroelectric pattern FE, the Te atom in the first layer 1F and the Te atom in the second layer 2F may move left and right. As an example, depending on the polarization state of the ferroelectric pattern FE, the Te and W atoms at the first layer 1F and the second layer 2F may move left and right.

Since the atomic structure and the arrangement are changed depending on the polarization state of the ferroelectric pattern FE, there may be a difference in transferred electron density to the first electrode pattern EL1 and to the second electrode pattern EL2 from the ferroelectric pattern FE depending on the polarization state. In FIG. 6, an x-axis represents the intensity of an electric field applied to the ferroelectric pattern FE, and a y-axis represents transferred electron density. Line A represents transferred electron density when in the up-polarization direction PLu, and line B represents transferred electron density when in the down-polarization direction PLd. As the intensity of the first electric field EF1 increases, the transferred electron density of the A and B lines may increase. As the intensity of the second electric field EF2 increases, the transferred electron density of the lines A and B may decrease. In addition, the transferred electron density of line A may be greater than the transferred electron density of line B, regardless of the direction and intensity of an electric field applied.

The difference in transferred electron density as described above can be seen from FIG. 7. First, a work function of a material (e.g., Pt) included in each of the first electrode pattern EL1 and the second electrode pattern EL2 may be greater than a work function of a material (e.g., WTe₂) included in the ferroelectric pattern FE. Accordingly, charge transfer may occur from the ferroelectric pattern FE to the first electrode pattern EL1 and the second electrode pattern EL2.

Depending on the polarization state of the ferroelectric pattern FE, the work functions may be different from each other, and accordingly, the transferred electron density from the ferroelectric pattern FE to the first electrode pattern EL1 and the second electrode pattern EL2 may be changed. When the ferroelectric pattern FE is in the up-polarization direction PLu, a work function of the ferroelectric pattern FE is about 4.40 [eV], which may be about 30 m[eV] smaller than that when the ferroelectric pattern FE is in the down-polarization direction PLd. Accordingly, the band bending of the ferroelectric pattern FE when in the up-polarization direction PLu may be greater than the band bending of the ferroelectric pattern FE when in the down-polarization direction PLd. As a result, a first depletion region DP1 formed when in the up-polarization direction PLu may be greater than a second depletion region DP2 formed when in the down-polarization direction PLd. Due to such a characteristic, transferred electron density TFu when in the up-polarization direction PLu may be greater than transferred electron density TFd when in the down-polarization direction PLd.

Due to such a difference in transferred electron density, there may be a difference between the contact resistance when in the up-polarization direction PLu and the contact resistance when in the down polarization direction PLd. Through the above-described characteristics, the contact resistance depending on the polarization state of the ferroelectric pattern FE may be changed, through which, the semiconductor device may be used as a contact resistance switching-based memory device.

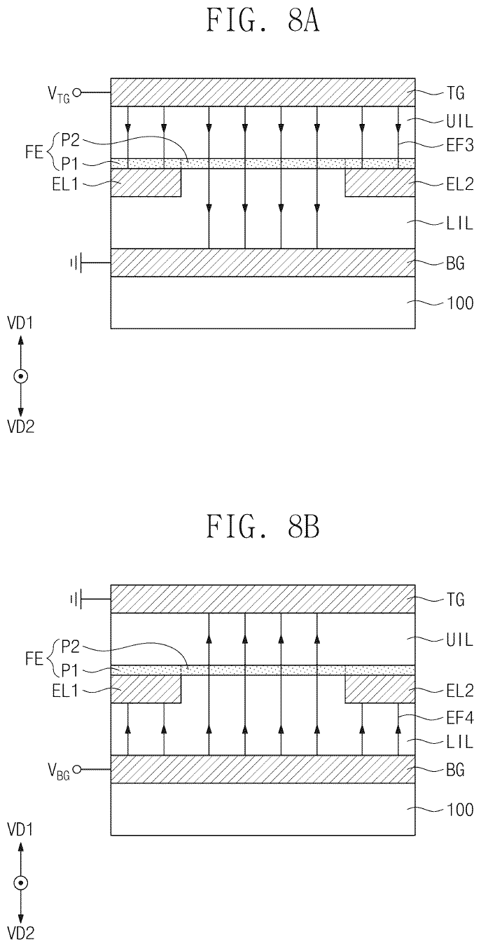

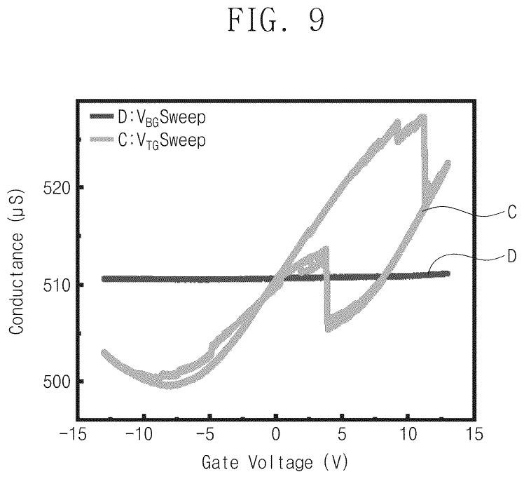

FIG. 8A and FIG. 8B are cross-sectional views showing a semiconductor device according to some embodiments of the present invention. FIG. 9 is a graph illustrating conductance of the ferroelectric pattern FE according to each of a voltage applied to the upper gate pattern TG of FIG. 8A, and a voltage applied to the lower gate pattern BG of FIG. 8B.

Referring to FIG. 8A, FIG. 8B, and FIG. 9, it will be described in detail that the contact resistance (R1 and R2 in FIG. 2C) of the ferroelectric pattern FE has a switching characteristic regardless of a switching characteristic of the internal resistance (R3 of FIG. 2C) of the ferroelectric pattern FE.

FIG. 8A shows that, as described with reference to FIG. 2A and FIG. 2B, a voltage V_{TG} may be applied to the upper gate pattern TG, and accordingly, a third electric field EF3 may be applied to the ferroelectric pattern FE. Although not illustrated in the drawing, when the voltage VTG is less than 0[V], the third electric field EF3 may be the first electric field EF1 of FIG. 2A, and a direction in which the third electric field EF3 is applied may be the vertical direction VD1. When the voltage VTG is greater than 0[V], the third electric field EF3 may be the second electric field EF2 of FIG. 2B, and a direction in which the third electric field EF3 is applied may be an opposite direction VD2 to the vertical direction VD1.

In FIG. 8B, a ground voltage may be applied to the upper gate pattern TG, and a voltage V_{BG} may be applied to the lower gate pattern BG. Accordingly, a fourth electric field EF4 may be applied to the ferroelectric pattern FE. If the voltage V_{BG} applied to the lower gate pattern BG is greater than 0[V], as illustrated in the drawing, the fourth electric field EF4 may be applied in the vertical direction VD1. Although not illustrated in the drawing, if the voltage V_{BG} applied to the lower gate pattern BG is less than 0[V], the fourth electric field EF4 may be applied in the opposite direction VD2 to the vertical direction VD1.

In FIG. 8B, if a fourth electric field EF4 having an intensity sufficient enough to change the polarization state of the ferroelectric pattern FE is applied in the vertical direction VD1 or the opposite direction VD2 to the vertical direction VD1, the polarization state of the second region P2 of the ferroelectric pattern FE may change.

On the other hand, the fourth electric field EF4 may be screened by the first electrode pattern EL1 and the second electrode pattern EL2, and accordingly, the first regions P1 of the ferroelectric pattern FE may not be affected by the fourth electric field EF4. As a result, even if the voltage V_{BG} is applied to the lower gate pattern BG, the polarization state of the first regions P1 of the ferroelectric pattern FE may not be changed.

Referring to FIG. 9, the above-described characteristics may be confirmed better. Specifically, an x-axis of FIG. 9 is a gate voltage, and corresponds to the voltage VTG applied to the upper gate pattern TG or the V_{BG} applied to the lower gate pattern BG. An y-axis corresponds to a conductance value of the ferroelectric pattern FE. Line C shows a change in the conductance value of the ferroelectric pattern FE according to a change in the voltage VTG applied to the upper gate pattern TG. Line D shows a change in the conductance value of the ferroelectric pattern FE according to a change in the voltage V_{BG} applied to the lower gate pattern BG.

In FIG. 9, according to a change in the voltage V_{TG} applied to the upper gate pattern TG, the line C may have a hysteresis curve of the conductance value of the ferroelectric pattern FE, as described with reference to FIG. 3A and FIG. 3B. Therefore, the contact resistance of the ferroelectric pattern FE may have a switching characteristic.

On the other hand, in FIG. 9, the line D may have substantially a constant value of conductance of the ferroelectric pattern FE according to a change in the voltage V_{BG} applied to the lower gate pattern BG. This is because there is no change in contact resistance, which has a dominant effect on the change in the value of conductance. As described above, the reason why there is no change in the contact resistance is that the polarization state of the first regions P1 of the ferroelectric pattern FE is not affected by the fourth electric field EF4 as the fourth electric field EF4 is screened by the first electrode pattern EL1 and the second electrode pattern EL2. Thus, it is not possible to utilize the semiconductor device of the present invention as a memory by utilizing a change in internal resistance according to a change in the polarization state of the second region P2 of the ferroelectric pattern FE. As described with reference to FIG. 2C, FIG. 3A, and FIG. 3B, the characteristics shown through the line D may be intensified if the length (L1 of FIG. 2C) of the second region P2 of the ferroelectric pattern FE is shortened, or the thickness (T1 of FIG. 2C) decreases.

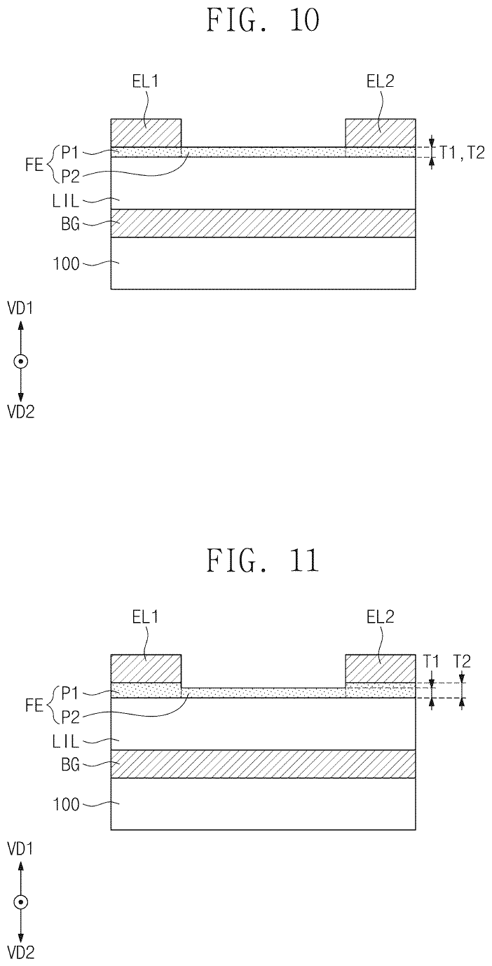

FIG. 10 is a cross-sectional view showing a semiconductor device according some embodiments of the present invention.

Referring to FIG. 10, in the semiconductor device described with reference to FIG. 1, the upper insulating film (UIL of FIG. 1) and the upper gate pattern (TG of FIG. 1) may be omitted. A ferroelectric pattern FE may be interposed between each of a first electrode pattern EL1 and a second electrode pattern EL2 and a lower gate pattern BG. Unlike FIG. 1, an upper surface of the ferroelectric pattern FE may come into contact with each of a lower surface of the first electrode pattern EL1 and a lower surface of the second electrode pattern EL2. Unlike FIG. 8B, the polarization state of first regions P1 of the ferroelectric pattern FE may be changed by an electric field formed by a voltage applied to the lower gate pattern BG. An operation method of the semiconductor device described with reference to FIG. 10 may be the same/similar to the operation method of a semiconductor device described with reference to FIG. 2A, FIG. 2B, FIG. 2C, FIG. 3A, and FIG. 3B.

FIG. 11 is a cross-sectional view showing a semiconductor device according some embodiments of the present invention.

Referring to FIG. 11, a thickness T2 of each of first regions P1 of a ferroelectric pattern FE may differ from a thickness T1 of a second region P2. The thickness T2 of each of the first regions P1 of the ferroelectric pattern FE may be greater than the thickness T1 of the second region P2. As an example, the second region P2 of the ferroelectric pattern FE may be a monolayer, and the first region P1 of the ferroelectric pattern FE may be a bilayer or more. Even if the thickness (T1) of the second region (P2) of the ferroelectric pattern (FE) decreases, the switching characteristics of the contact resistance of the ferroelectric pattern (FE) can be maintained. Even if the thickness T1 of the second region P2 of the ferroelectric pattern FE decreases, the switching characteristic of contact resistance of the ferroelectric pattern FE may be maintained. Therefore, as the thickness Tl of the second region P2 of the ferroelectric pattern FE decreases, a memory characteristic of the semiconductor device may be maintained, but the integration of the semiconductor device may be improved.

An operation method of the semiconductor device described with reference to FIG. 11 may be the same/similar to the operation method of a semiconductor device described with reference to FIG. 2A, FIG. 2B, FIG. 2C, FIG. 3A, and FIG. 3B.

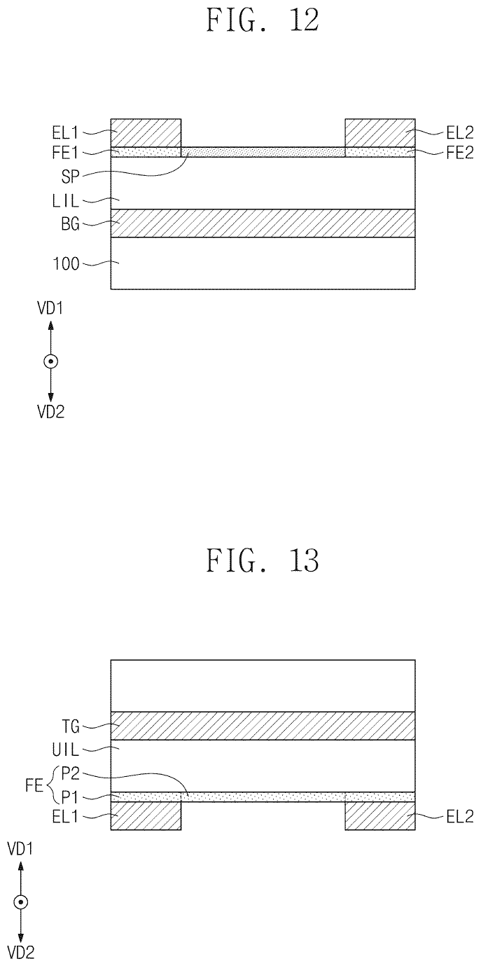

FIG. 12 is a cross-sectional view showing a semiconductor device according some embodiments of the present invention.

Referring to FIG. 12, a semiconductor device capable of performing an in-memory computing operation will be described in detail below. The in-memory computing refers to a technology in which not only data storage but also data calculation (i.e., computing) may be performed together in a memory device.

Referring to FIG. 12, the second region (P2 of FIG. 1) of the ferroelectric pattern FE described with reference to FIG. 1 may be replaced with a semiconductor pattern SP. The semiconductor pattern SP may include at least one of a single crystalline semiconductor, a polycrystalline semiconductor, an oxide semiconductor, and a two-dimensional material. For example, the single crystalline semiconductor may be single crystalline silicon. As an example, the polycrystalline semiconductor may be polysilicon.

One of the first regions (P1 of FIG. 1) of the ferroelectric pattern FE described with reference to FIG. 1 may constitute a first ferroelectric pattern FE1, and the other one may constitute a second ferroelectric pattern FE2.

As described with reference to FIG. 2A, FIG. 2B, FIG. 2C, FIG. 3A, and FIG. 3B, the semiconductor device may perform a memory function by utilizing the switching of contact resistance between the first ferroelectric pattern FEL and the first electrode pattern EL1 and contact resistance between the second ferroelectric pattern FE2 and the second electrode pattern EL2.

In addition to the corresponding function, the semiconductor device may also perform a data calculation (computing) function since the semiconductor pattern SP is interposed between the first ferroelectric pattern FE1 and the second ferroelectric pattern FE2. Specifically, the semiconductor pattern SP may perform a function as a channel region of a transistor. The first electrode pattern EL1 may function as a source region together with the first ferroelectric pattern FE1, and the second electrode pattern EL2 may function as a drain region together with the second ferroelectric pattern FE2. In other words, the semiconductor pattern SP, the first electrode pattern EL1, the first ferroelectric pattern FE1, the second electrode pattern EL2, and the second ferroelectric pattern FE2 may constitute one transistor. Depending on a voltage applied to the lower gate pattern BG, a channel may or may not be formed in the semiconductor pattern SP. In other words, depending on a voltage applied to the lower gate pattern BG, the transistor may be turned on or off.

In summary, the semiconductor device described with reference to FIG. 12 may perform a memory function utilizing switching of contact resistance and may simultaneously perform a computing function of a transistor. Therefore, the semiconductor device may perform the above-described in-memory computing operation.

FIG. 13 is a cross-sectional view showing a semiconductor device according some embodiments of the present invention.

Referring to FIG. 13, in the semiconductor device described with reference to FIG. 1, the lower insulating layer (LIL of FIG. 1) and the lower gate pattern (BG of FIG. 1) may be omitted. Although not illustrated in the drawing, an insulating layer (not shown) covering the first electrode pattern EL1 and the second electrode pattern EL2, and a substrate (not shown) under the insulating layer may be provided.

An operation method of the semiconductor device described with reference to FIG. 13 may be the same/similar to the operation method of a semiconductor device described with reference to FIG. 2A, FIG. 2B, FIG. 2C, FIG. 3A, and FIG. 3B.

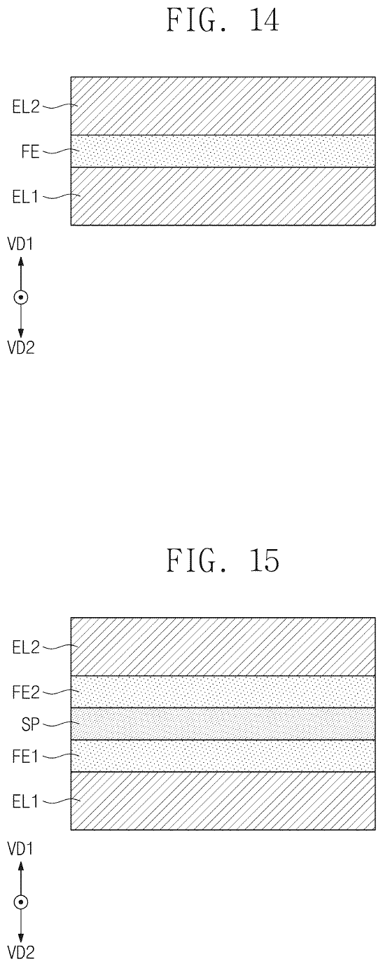

FIG. 14 is a cross-sectional view showing a semiconductor device according some embodiments of the present invention.

Referring to FIG. 14, unlike the semiconductor device described with reference to FIG. 1, a first electrode pattern ELI and a second electrode pattern EL2 may be arranged to be spaced apart from each other in a vertical direction VD1. A ferroelectric pattern FE may be interposed between the first electrode pattern EL1 and the second electrode pattern EL2. A lower surface of the ferroelectric pattern FE may be in contact with the first electrode pattern EL1. An upper surface of the ferroelectric pattern FE may be in contact with the second electrode pattern EL2. Accordingly, contact resistance may be formed between the ferroelectric pattern FE and the first electrode pattern EL1, and between the ferroelectric pattern FE and the second electrode pattern EL2.

An electric field may be applied to the ferroelectric pattern FE by a voltage applied to the first electrode pattern EL1 and the second electrode pattern EL2. Accordingly, a polarization direction of the ferroelectric pattern FE may be changed. As described above, since the polarization direction of the ferroelectric pattern FE is changed, contact resistance between the ferroelectric pattern FE and the first electrode pattern EL1 and contact resistance between the ferroelectric pattern FE and the second electrode pattern EL2 may be changed. By utilizing the above-described contact resistance switching characteristic, the semiconductor device described with reference to FIG. 14 may be utilized as a contact resistance switching-based memory device, like the semiconductor device described with reference to FIG. 1.

FIG. 15 is a cross-sectional view showing a semiconductor device according some embodiments of the present invention.

Referring to FIG. 15, unlike the semiconductor device described with reference to FIG. 1, a first electrode pattern ELI and a second electrode pattern EL2 may be arranged to be spaced apart from each other in a vertical direction VD1. A first ferroelectric pattern FEL and a second ferroelectric pattern FE2 may be arranged to be spaced apart from each other in a vertical direction VD1 between the first electrode pattern EL1 and the second electrode pattern EL2. A semiconductor pattern SP may be interposed between the first ferroelectric pattern FEL and the second ferroelectric pattern FE2. As an example, the semiconductor pattern SP may include a material which is the same as or similar to the material included in the semiconductor pattern SP described with reference to FIG. 12.

A lower surface of the first ferroelectric pattern FE1 may be in contact with the first electrode pattern EL1, and an upper surface of the first ferroelectric pattern FE1 may be in contact with the semiconductor pattern SP, so that contact resistance may be formed between the lower surface of the first ferroelectric pattern FE1 and the first electrode pattern EL1 and the upper surface of the first ferroelectric pattern FEL and the semiconductor pattern SP. A lower surface of the second ferroelectric pattern FE2 may be in contact with the semiconductor pattern SP, and an upper surface of the second ferroelectric pattern FE2 may be in contact with the second electrode pattern EL2, so that contact resistance may be formed between lower surface of the second ferroelectric pattern FE2 and the semiconductor pattern SP between the upper surface of the second ferroelectric pattern FE2 and the second electrode pattern EL2.

An electric field may be applied to the ferroelectric pattern FE by a voltage applied to the first electrode pattern EL1 and the second electrode pattern EL2. Accordingly, a polarization direction of the ferroelectric pattern FE may be changed. As described above, since the polarization direction of the ferroelectric pattern FE is changed, contact resistance between the first ferroelectric pattern FEL and each of the first electrode pattern EL1 and the semiconductor pattern SP, and contact resistance between the second ferroelectric pattern FE2 and each of the second electrode pattern EL2 and the semiconductor device SP may be changed. By utilizing the above-described contact resistance switching characteristic, the semiconductor device described with reference to FIG. 15 may be utilized as a contact resistance switching-based memory device, like the semiconductor device described with reference to FIG. 1.

According to the concept of the present invention, contact resistance between a ferroelectric pattern and an electrode pattern may be switched according to a polarization direction of the ferroelectric pattern. By utilizing the characteristic in which contact resistance is switched, a semiconductor device may be utilized as a contact resistance switching-based memory device. Therefore, a semiconductor device of the present invention may provide a new type of memory device.

Furthermore, the semiconductor device of the present invention may not be affected by a short channel effect compared to a memory device utilizing switching of channel resistance of a ferroelectric pattern. As the channel length of the ferroelectric pattern decreases, the switching characteristic of the channel resistance may be affected by a voltage applied to electrode patterns. On the other hand, even if the channel length decreases, the switching characteristic of the contact resistance between the ferroelectric pattern and the electrode pattern may not be affected. Accordingly, the semiconductor device of the present invention, which is utilized as a contact resistance switching-based memory device, may be formed to have a small channel length. Thus, the integration of the semiconductor device may be improved.

In addition, if the ferroelectric pattern becomes a monolayer, a switching characteristic of the channel resistance of the ferroelectric pattern may not be found. Accordingly, a semiconductor device which utilizes the switching of the channel resistance of the ferroelectric pattern may not be utilized as a memory device. On the other hand, since the contact resistance of the semiconductor device of the present invention is formed at a contact surface of the ferroelectric pattern and the electrode pattern, the switching characteristic of the contact resistance may not be affected by the thickness of the ferroelectric pattern. Accordingly, the semiconductor device of the present invention, which is utilized as a contact resistance switching-based memory device, may be formed to have a small thickness of the ferroelectric pattern. Thus, the integration of the semiconductor device may be improved.

The above description of the embodiments of the present invention provides examples for the description of the present invention. Therefore, the present invention is not limited to the above embodiments, and it is apparent that many modifications and changes may be made, such as by combining the above embodiments by those of ordinary skill in the art within the inventive concept.

What is claimed is:

1. A method for operating a semiconductor device, the method comprising:
applying a first bias voltage to a gate pattern; and
storing first data in response to the first bias voltage,
wherein:
contact resistance between an electrode pattern and a ferroelectric pattern is changed from a first resistance state to a second resistance state in response to the first bias voltage;
the first data is stored based on the change from the first resistance state to the second resistance state; and
the ferroelectric pattern is interposed between the gate pattern and the electrode pattern.

2. The method of claim 1, wherein:
resistance of the second resistance state is less than resistance of the first resistance state; and
storing of the first data includes storing data “1.”

3. The method of claim 1, further comprising:
after storing of the first data, and then applying a first read voltage to the gate pattern;
applying a second read voltage to the electrode pattern;
measuring resistance of the second resistance state of the contact resistance between the electrode pattern and the ferroelectric pattern in response to the first read voltage and the second read voltage; and
reading the first data by measuring the resistance of the second resistance state.

4. The method of claim 3, wherein the first read voltage is greater than 0[V].

5. The method of claim 3, wherein the first read voltage is less than 0[V].

6. The method of claim 1, wherein polarization of the ferroelectric pattern is changed to an up-polarization direction in response to the first bias voltage, and the contact resistance between the electrode pattern and the ferroelectric pattern is changed from the first resistance state to the second resistance state based on the change in the polarization of the ferroelectric pattern.

7. The method of claim 6, further comprising:
applying a second bias voltage to the gate pattern; and
storing second data in response to the second bias voltage, wherein:
the polarization of the ferroelectric pattern is changed from the up-polarization direction to a down-polarization direction in response to the second bias voltage; and
the contact resistance between the electrode pattern and the ferroelectric pattern is changed from the second resistance state to the first resistance state based on the change in the polarization of the ferroelectric pattern from the up-polarization direction to the down-polarization direction.

8. The method of claim 7, wherein:
resistance of the first resistance state is greater than resistance of the second resistance state; and
storing of the second data includes storing data “0.”

9. The method of claim 1, wherein:
polarization of the ferroelectric pattern is changed to a down-polarization direction in response to the first bias voltage, and
the contact resistance between the electrode pattern and the ferroelectric pattern is changed from the first resistance state to the second resistance state based on the change in the polarization of the ferroelectric pattern.

10. The method of claim 9, further comprising:
applying a second bias voltage to the gate pattern; and
storing second data in response to the second bias voltage,
wherein the polarization of the ferroelectric pattern is changed from the down-polarization direction to an up-polarization direction in response to the second bias voltage, and the contact resistance between the electrode pattern and the ferroelectric pattern is changed from the second resistance state to the first resistance state based on the change in the polarization of the ferroelectric pattern from the down-polarization direction to the up-polarization direction.

11. The method of claim 1, further comprising after storing of the first data, and then applying a second bias voltage to the gate pattern,
wherein the contact resistance between the light electrode pattern the ferroelectric pattern is changed from the second resistance state to the first resistance state in response to the second bias voltage; and the contact resistance between the electrode pattern and the ferroelectric pattern follows a hysteresis loop.

12. The method of claim 1, wherein the ferroelectric pattern comprises at least one of WTe₂, MoTe₂, Mo_{0.5}W_{0.5}Te₂, In₂Se₃, SnS, SnTe, MoS₂/MoS₂, and MoS₂/WS₂.

13. The method of claim 1, wherein the electrode pattern comprises a first electrode pattern and a second electrode pattern on the ferroelectric pattern,
wherein:
the ferroelectric pattern includes first regions vertically overlapping the first electrode pattern and the second electrode pattern, and a second region between the first regions; and
the length of the second region of the ferroelectric pattern is 10 nm to 500 nm.

14. The method of claim 1, wherein the electrode pattern comprises a first electrode pattern and a second electrode pattern on the ferroelectric pattern,
wherein:
the first electrode pattern and the second electrode pattern, and a second region between the first regions; and
the second region of the ferroelectric pattern is a monolayer.

15. A semiconductor device comprising:
a substrate;
a ferroelectric pattern on the substrate;
an electrode pattern in contact with the ferroelectric pattern between the) ferroelectric pattern and the substrate; and
a gate pattern adjacent to the ferroelectric pattern, and configured to control the direction of polarization of the ferroelectric pattern,
wherein:
the ferroelectric pattern is interposed between the gate pattern and the electrode pattern;
contact resistance between the ferroelectric pattern and the electrode pattern is changed from a first resistance state to a second resistance state in response to a first bias voltage applied to the gate pattern; and
first data is stored based on the change from the first resistance state to the second resistance state.

16. The semiconductor device of claim 15, wherein the electrode pattern comprises a first electrode pattern and a second electrode pattern on the ferroelectric pattern,
wherein:
the first electrode pattern and the second electrode pattern, and a second region between the first regions; and
the length of the second region of the ferroelectric pattern is 10 nm to 500 nm.

17. The semiconductor device of claim 15, wherein the electrode pattern comprises a first electrode pattern and a second electrode pattern on the ferroelectric pattern,
wherein:
the ferroelectric pattern includes first regions vertically overlapping the first electrode pattern and the second electrode pattern, and a second region between the first regions; and
the second region of the ferroelectric pattern is a monolayer.

18. The semiconductor device of claim 15, wherein the electrode pattern comprises a first electrode pattern and a second electrode pattern on the ferroelectric pattern,
wherein:
the ferroelectric pattern includes first regions vertically overlapping the first electrode pattern and the second electrode pattern, and a second region between the first regions; and
the thickness of each of the first regions of the ferroelectric pattern is greater than the thickness of the second region.

19. The semiconductor device of claim 15, wherein the electrode pattern comprises a first electrode pattern and a second electrode pattern on the ferroelectric pattern,
wherein:
the ferroelectric pattern includes a first ferroelectric pattern in contact with the first electrode pattern and a second ferroelectric pattern in contact with the second electrode pattern, and
the ferroelectric pattern further includes a semiconductor pattern between the first ferroelectric pattern and the second ferroelectric pattern.

20. The semiconductor device of claim 15, wherein:
resistance of the second resistance state is less than resistance of the first resistance state; and
the contact resistance between the ferroelectric pattern and the electrode pattern is changed from the second resistance state to the first resistance state in response to a second bias voltage applied to the gate pattern; and
storing second data based on the change in the contact resistance between the ferroelectric pattern and the electrode pattern from the second resistance state to the first resistance state.
